(19) United States
(12) Patent Application Publication
(10) Pub. No.: US 2012/0291845 A1
(43) Pub. Date: Nov. 22, 2012

(54) SOLAR CELL BACKSHEET AND SOLAR CELL MODULE

(76) Inventors: Akira Hatakeyama, Shizuoka (JP); Toshihiro Oda, Shizuoka (JP)

(21) Appl. No.: 13/574,082

(22) PCT Filed: Jan. 25, 2011
(86) PCT No.: PCT/JP2011/051848

§ 371 Date: Jul. 19, 2012

(30) Foreign Application Priority Data
Feb. 10, 2010 (JP) 2010-027998

(51) Int. Cl. H01L 31/052; B32B 27/36; G02B 5/08; B32B 27/40; B32B 27/32; B32B 27/30; B32B 5/30; B32B 27/20

(52) U.S. Cl. 136/244; 428/688; 428/480; 428/702; 428/340; 428/323; 428/423.1; 428/500; 428/522; 428/336; 428/354; 359/883

(57) ABSTRACT

The present invention provides a backsheet for a solar cell including a polymer base material and a reflection layer, the backsheet being light weight and having a large light reflectance, the polymer base material including first white inorganic particles in an amount of from 10% by mass to 30% by mass with respect to a total mass of the polymer base material, the reflection layer being formed by being coated on at least one side of the polymer base material, and the reflection layer including a binder, and second white inorganic particles in a content of from 30% by mass to 90% by mass with respect to a total mass of the binder and the second white inorganic particles; and a solar cell module which has adequate power generation efficiency.

### BACKGROUND OF THE INVENTION

1. Technical Field

The present invention relates to a backsheet for a solar cell, the backsheet being placed on an opposite side of a sunlight incident side of a solar cell element, and to a solar cell module.

2. Background Art

Solar cells are electricity generating systems that discharge no carbon dioxide on electric power generation and have a small burden on the environment. Solar cells have been spreading rapidly in recent years.

A solar cell module has a structure in which solar cells are sandwiched between a front face glass on a sunlight incident side and a so-called backsheet that is placed on the opposite side (rear side) of the sunlight incident side. A space between the front face glass and the solar cells and a space between the solar cells and the backsheet are sealed respectively with an EVA (ethylene-vinylacetate) resin or the like.

The backsheet serves to prevent moisture penetration from the rear face of the solar cell module. Conventionally, glass, fluoro resin or the like was used for the backsheet, but in recent years, considering cost, polyester has started to be used. The backsheet is not merely a polymer sheet, but depending on circumstances, is provided with various functions as described below.

For example, a backsheet, which has white inorganic particles, such as titanium oxide, added therein so as to be provided with a function of reflection as one of the above functions, is demanded in some cases. This is for the purpose of increasing efficiency of electric power generation by means of returning back to the cells by diffuse reflection (hereinafter, referred to as simply “reflection”) sunlight that has entered from the front face of the module and passed through the cells. Regarding this point, an example of a white polyethylene terephthalate film that includes white inorganic particles added therein has been disclosed (see, Japanese Patent Application Laid-Open (JP-A) Nos. 2003-060218 and 2006-210557, for example). In addition, an example of a rear face protecting sheet with a white ink layer that includes a white pigment therein has been also disclosed (see, JP-A No. 2006-210557, for example).

### SUMMARY OF THE INVENTION

According to an aspect of the invention, a backsheet for a solar cell including a polymer base material and a reflection layer, the backsheet being light weight and having a large light reflectance, the polymer base material including first white inorganic particles in an amount of from 10% by mass to 30% by mass with respect to a total mass of the polymer base material, the reflection layer being formed by being coated on at least one side of the polymer base material, and the reflection layer including a binder, and second white inorganic particles in a content of from 30% by mass to 90% by mass with respect to a total mass of the binder and the second white inorganic particles; and a solar cell module which has adequate power generation efficiency, are provided.

### Technical Problem

In order to enhance power generation efficiency still higher, the reflectance of the backsheet needs to be increased. Therefore, the addition amount of white inorganic particles needs to be increased.

On the other hand, as the solar cell module becomes larger in size, weight saving is strongly needed. In particular, this need is strong in Japan where solar cell modules are installed on roofs of existing buildings in many cases. Even in a case in which a resin such as polyester that is lightweight as compared with glass is used, there is a problem in that the weight of the backsheet increases when the white inorganic particles are added in a large amount, because the white inorganic particles are greater in density than the resin.

Specifically, in order to attain a high reflectance, the white inorganic particles need to be used in a large amount. When only the amount of the white inorganic particles is increased while the amount of a polymer is kept unchanged in the backsheet, the strength of the backsheet is lowered or the appearance thereof is degraded. Therefore, in order to increase the amount of the white inorganic particles, the polymer included in the backsheet needs to be increased at the same time. In this way, when the white inorganic particles are increased while the ratio of white inorganic particles to polymer is kept unchanged, the weight of the backsheet increases.

Namely, high reflectance and weight saving cannot be attained at the same time by conventional methods, and a light weight backsheet with high reflectance has been demanded.

The present invention has been accomplished in view of the above circumstances. An object of the present invention is to provide a backsheet for a solar cell, the backsheet being light weight and having a large reflectance of light, and a solar cell module that has adequate power generation efficiency.

### Solution to Problem

As a result of intensive studies, the present inventors have found that the reflectance of a polymer base material may be enhanced efficiently by only incorporating a small amount of white inorganic particles therein. The present inventors have also found that the strength and appearance of the backsheet are not easily degraded even though the amount of white inorganic particles increases in a reflection layer as compared with the polymer base material. The present invention is based on this finding.

Exemplary embodiments of the present invention include the following.

<1> A backsheet for a solar cell, the backsheet including: a polymer base material including first white inorganic particles in an amount of from 10% by mass to 30% by mass with respect to a total mass of the polymer base material; and a reflection layer that is formed by being coated on at least one side of the polymer base material, the reflection layer including a binder and second white inorganic particles in an amount of from 30% by mass to 90% by mass with respect to a total mass of the binder and the second white inorganic particles.

<2> The backsheet for a solar cell according to the item <1>, wherein the polymer base material is a polyester.

<3> The backsheet for a solar cell according to the item <1> or the item <2>, wherein at least one of the first white inorganic particles or the second white inorganic particles is titanium dioxide.

<4>. The backsheet for a solar cell according to any one of the items <1> to <3>, wherein an amount of the second white inorganic particles in the reflection layer is in a range of from 4 g/m² to 12 g/m².

<5> The backsheet for a solar cell according to any one of the items <1> to <4>, wherein a volume average particle diameter of the first white inorganic particles and/or the second white inorganic particles is in a range of from 0.03 μm to 0.8 μm.

<6> The backsheet for a solar cell according to any one of the items <1> to <5>, wherein the binder is selected from the group consisting of polyester, polyurethane, acrylic resin and polyolefin.

<7> The backsheet for a solar cell according to any one of the items <1> to <6> further including an under coating layer,between the polymer base material and the reflection layer, the under coating layer having a thickness in a range of from 0.05 μm to 2 μm.

<8> The backsheet for a solar cell according to any one of the items <1> to <7> further including an adhesive layer on an opposite side of the polymer base material to which the reflection layer is disposed.

<9> The backsheet for a solar cell according to any one of the items <1> to <8>, wherein a reflectance is 85% or more when an incident light having a wavelength of 550 nm is radiated toward a side where the reflection layer is disposed.

<10> A module for a solar cell, the module including the backsheet for a solar cell according to any one of the items <1> to <9>.

### DETAILED DESCRIPTION OF THE INVENTION

Hereinafter, a solar cell backsheet according to the present invention, a method of producing the same, and a solar cell module will be described in detail.

Solar Cell Backsheet and Method of Producing the Same

A backsheet according to the present invention is composed of a polymer base material and a reflection layer. The polymer base material includes first white inorganic particles therein in an amount of from 10% by mass to 30% by mass with respect to the total mass thereof. The reflection layer is formed by being coated on at least one side of the polymer base material and includes therein a binder and second white inorganic particles. The content of the second white inorganic particles with respect to the total mass of the binder and the second white inorganic particles is from 30% by mass to 90% by mass.

In the present invention, the polymer base material and the reflection layer include white inorganic particles therein respectively.

The white inorganic particles that are included in the polymer base material and the reflection layer may be the same or different. The white inorganic particles that are included in the polymer base material are referred to as first white inorganic particles. The white inorganic particles that are included in the reflection layer are referred to as second white inorganic particles.

As already mentioned, the solar cell backsheet has, for the purpose of increasing power generation efficiency, a function of reflecting sun light that has entered from a front face of the module and passed through the cells and returning the sun light back to the cells. At this time, the sun light that has passed through the cells is mostly reflected on the reflection layer formed on the polymer base material. However, in addition to that, in order to reflect the sun light that has passed even through the reflection layer on the polymer base material, the polymer base material includes the white inorganic particles therein.

As the content of the white inorganic particles is larger, the reflection amount of the sun light becomes larger and power generation efficiency may be increased. However, on the other hand, as described above, when the content of the white inorganic particle is too large, the weight of the solar cell backsheet increases and also the strength of the sheet is easily degraded.

On this occasion, by configuring in a manner as described above the solar cell backsheet that has the polymer base material and the reflection layer therein, a lightweight solar cell backsheet, in which the weight thereof is suppressed while the reflectance thereof is increased, may be attained.

Hereinafter, the polymer base material and the reflection layer that compose the solar cell backsheet according to the present invention will be described in detail.

[Polymer Base Material]

Examples of polymer base materials include polyester; polyolefin such as polypropylene, polyethylene; fluorocarbon based polymer such as polyvinyl fluoride; and the like. Among above, polyester is preferable from viewpoints of cost, mechanical strength and the like.

Polyester usable in exemplary embodiments of the invention as a polymer base material (support) is saturated linear polyester synthesized by a reaction of an aromatic dibasic acid or an ester formable derivative thereof with a diol or an ester formable derivative thereof. Examples of the polyester include polyethylene terephthalate, polyethylene isophthalate, polybutylene terephthalate, poly 1,4-cyclohexylenedimethylene terephthalate, polyethylene 2,6-naphthalate and the like. Among them, polyethylene terephthalate or polyethylene 2,6-naphthalate is preferable from viewpoint of a balance of mechanical strength, cost and the like.

The polyester may be a homo-polymer or a co-polymer. In addition, the polyester may be blended with a small amount of the other kinds of reins such as polyimide.

When the polyester of the present invention is polymerized, from the viewpoint of suppressing the amount of carboxy group within a predetermined range, a compound of Sb-based, Ge-based, or Ti-based is preferably used as a catalyst. Among these, a Ti-based compound is particularly preferable. When the Ti-based compound is used, in a preferred embodiment, polymerization is performed by using the Ti-based compound as a catalyst in an amount of from 1 ppm to 30 ppm and more preferably from 3 ppm to 15 ppm. When the amount of the Ti-based compound is in the above range, end carboxy group may be adjusted within the following range, and hydrolysis resistance of the polymer base material may be kept low.

Polyester synthesis using the titanium-based compound may be performed by applying a method described in Japanese published examined application patent No. 8-301,198, Japanese patent Nos. 2,543,624, 3,335,683, 3,717,380, 3,897,756, 3,962,226, 3,979,866, 3,996,871, 4,000,867, 4,053,837, 4,127,119, 4,134,710, 4,159,154, 4,269,704, 4,313,538, and the like.

The content of carboxy group in the polyester is preferably 50 eq. (equivalent)/t or less and more preferably 35 eq./t or less. When the content of carboxy group is 50 eq./t or less, hydrolysis resistance may be kept unchanged and lowering in the strength after storage under a wet and heat condition may be suppressed small. The lower limit of the content of carboxy group is 2 eq./t desirably, from the viewpoint of keeping adhesion to a layer (for instance, a color layer) that is formed on the polyester.

The content of carboxy group in the polyester may be adjusted by selecting the kind of the catalyst and film forming conditions (film forming temperature or time).

The polyester of the present invention is preferably subjected to solid phase polymerization after polymerization. By means of this, a preferable content of carboxy group may be attained. Solid phase polymerization may be performed in a continuous process (a process where a tower is filled with resins; the resins are made to stagnate slowly for a predetermined time while heated; and then the resins are fed out), or a batch-wise process (a process where resins are loaded in a container, and then heated for a predetermined time). Specifically, a synthetic method described in Japanese patent Nos. 2,621,563, 3,121,876, 3,136,774, 3,603,585, 3,616,522, 3,617,340, 3,680,523, 3,717,392, 4,167,159, and the like, is applicable to the solid phase polymerization of polyester.

The solid phase polymerization of the polyester is preferably performed at a temperature in a range of from 170° C. or higher and 240° C. or lower, more preferably in a range of from 180° C. or higher and 230° C. or lower, and even more preferably in a range of from 190° C. or higher and 220° C. or lower. The solid phase polymerization of the polyester is preferably performed in a vacuum or under nitrogen gas atmosphere.

The polyester base material of the present invention is preferably a biaxially stretched film, which is stretched for instance as: the above polyester is fused and extruded into a film-form; the film-form polyester is cooled and solidified with a casting drum into a non-stretched film; the non-stretched film is stretched in a longitudinal direction at a temperature of from Tg to (Tg+60)° C. one time or two or more times in a manner that total stretch becomes from 3 times to 6 times; and then the film is further stretched in a transverse direction at a temperature of from Tg to (Tg+60)° C. in a manner that total stretch becomes from 3 times to 5 times.

The polyester base material may be further subjected to heat treatment for from 1 sec to 60 sec at a temperature of from 180° C. to 230° C., when needed.

The thickness of the polymer base material (particularly, polyester base material) is preferably from 25 μm to 150 μm. A thickness of 25 μm or more provides an adequate mechanical strength. A thickness of 150 μm or less is advantageous in weight.

White Inorganic Particles (First White Inorganic Particles)

The polymer base material of the present invention includes at least one kind of white inorganic particles therein. The content of the white inorganic particles in the polymer base material is from 10% by mass to 30% by mass with respect to the total mass of the polymer base material.

As a white inorganic pigment, for instance, an inorganic pigment such as titanium dioxide, barium sulfate, silicon oxide, aluminum oxide, magnesium oxide, calcium carbonate, kaolin, or talc may be appropriately selected and included therein. Among these, titanium dioxide is preferable.

The average particle size of the white inorganic particles is preferably from 0.03 μm to 0.8 μm in terms of volume average particle size, and more preferably from 0.15 μm to 0.5 μm or from about 0.15 μm to about 0.5 μm. When the average particle size is in the above range, light reflectance is high. The average particle size is represented by a value that is measured with a laser diffraction particles size distribution analyzer “LA-950” (manufactured by HORIBA, Ltd.).

The polymer base material of the present invention includes the above white inorganic particles in an amount of from 10% by mass to 30% by mass with respect to the total mass of the polymer base material, but more preferable range of the addition amount of the white inorganic particles is from 12% by mass to 20% by mass. When the content of the white inorganic particles in the polymer base material is not 10% by mass or more, an adequate reflectance is not attained. When the content is not 30% by mass or less, an adequate property (a support having no cracks) is not attained.

Note that, when the polymer base material includes two or more kinds of white inorganic particles, the total content of all of the white inorganic particles in the polymer base material needs to be in a range of from 10% by mass to 30% by mass.

Reflection Layer

The reflection layer of the present invention is formed by being coated on at least one face side of a support and includes a binder and white inorganic particles (second white inorganic particles) therein. The amount of the white inorganic particles included in the reflection layer is from 30% by mass to 90% by mass with respect to the total mass of the binder and the white inorganic particles in the reflection layer.

The reflection layer may further include the other components such as various kinds of additives therein, when needed.

White Inorganic Particles (Second White Inorganic Particles)

The reflection layer of the present invention includes at least one kind of white inorganic particles therein.

A white inorganic pigment may be the same or different from the white inorganic particles that are included in the polymer base material. For instance, an inorganic pigment such as titanium dioxide, barium sulfate, silicon oxide, aluminum oxide, magnesium oxide, calcium carbonate, kaolin, or talc may be appropriately selected and included therein. Among these, titanium dioxide is preferable.

The reflection layer of the present invention includes the white inorganic particles in an amount of from 30% by mass to 90% by mass with respect to the total mass of the binder and white inorganic particles in the reflection layer. A more preferable range of the addition amount of the white inorganic particles is from 50% by mass to 85% by mass. When the content of the white inorganic particles in the reflection layer is not 30% by mass or more, an adequate reflectance is not attained. When the content is not 90% by mass or less, the solar cell backsheet is not provided with weight saving.

In the reflection layer of the present invention, the white inorganic particles are included in a range of preferably from 4 g/m² to 12 g/m². When the content of the white inorganic particles is 4 g/m² or more, a necessary reflectance is easily attained. When the content is 12 g/m², a polymer sheet is easily provided with weight saving.

In particular, a more preferable content of the white inorganic particles in the reflection layer is in a range of from 5 g/m² to 11 g/m².

Note that, when the reflection layer includes two or more kinds of white inorganic particles, the total addition amount of all of the white inorganic particles included in the reflection layer needs to be in a range of from 4 g/m² to 12 g/m².

The average particle size of the white inorganic particles is preferably from 0.03 μm to 0.8 μm in terms of volume average particle size, and more preferably from 0.15 μm to 0.5 μm or from about 0.15 μm to about 0.5 μm. When the average particle size is in the above range, light reflection efficiency is high. The average particle size is represented by a value that is measured with a laser diffraction particles size distribution analyzer “LA-950” (manufactured by HORIBA, Ltd.).

Binder

The reflection layer of the present invention includes at least one kind of binder therein.

The coated amount of the binder is preferably in a range of from 0.3 g/m² to 13 g/m², and more preferably in a range of from 0.4 g/m² to 11 g/m². When the coated amount of the binder is 0.3 g/m² or more, a color layer is provided with sufficient strength. In the case of 13 g/m² or less, the reflectance and weight may be kept properly.

A suitable binder for the reflection layer of the present invention is polyester, polyurethane, acrylic resin, polyolefin, and the like. From the viewpoint of durability, acrylic resin and polyolefin are preferable. As the acrylic resin, a composite resin of acryl and silicone is also preferable. Examples of a preferred binder include: “CHEMIPEARL S-120” and “CHEMIPEARL S-75N” (trade names: both are manufactured by MITSUI CHEMICALS, INC.), which are examples of the polyolefin; “JURYMER ET-41” and “JURYMER SEK-301” (trade names: both are manufactured by Nihon Junyaku Co., Ltd.), which are examples of the acrylic resin; and “CERANATE WSA1060” and “SERANATE WSA1070” (trade names: both are manufactured by DIC Corp.) and “H7620”, “H7630”, and “H7650” (trade names: all of them are manufactured by ASAHI KASEI CHEMICALS CORP.), which are examples of the composite resin of acryl and silicone.

Additives

To the reflection layer of the present invention, besides the binder and the white inorganic particles, additives such as a cross-linking agent, a surfactant, or filler may be further added when needed.

Examples of the cross-linking agent include cross-linking agents of epoxy-based, isocyanate-based, melamine-based, carbodiimide-based, and oxazoline-based. Among these, an oxazoline-based cross-linking agent is preferable. Specifically, the one that is usable for an easy-to-adhere layer described later may be suitably used.

When the cross-linking agent is added, the addition amount thereof is preferably from 5% by mass to 50% by mass and more preferably from 10% by mass to 40% by mass with respect to a binder included in the color layer. When the addition amount of the cross-linking agent is 5% by mass or more, a sufficient cross-linking effect is obtained while strength and adhesiveness of the color layer are kept. In the case where the addition amount of the cross-linking agent is 50% by mass or less, pot life of a coating liquid may be kept long.

Examples of the surfactant include known surfactants such as anionic or nonionic ones. When the surfactant is added, the addition amount thereof is preferably from 0.1 mg/m² to 15 mg/m² and more preferably from 0.5 mg/m² to 5 mg/m². When the addition amount of the surfactant is 0.1 mg/m² or more, adequate formation of layers may be attained while repelling is prevented from being generated. In the case of 15 mg/m² or less, bonding may be performed properly.

In the reflection layer of the present invention, besides the above white inorganic particles, filler or the like such as silica may be added, additionally. When the filler is added, the addition amount thereof is preferably 20% by mass or less with respect to the binder in the color layer, and more preferably 15% by mass or less. When the addition amount of the filler is 20% by mass or less, necessary reflectance and adhesion to a support may be attained.

Method of Forming Reflection Layer

The reflection layer of the present invention is formed by being applied, on at least one face side of a support, a coating liquid for a reflection layer. The coating liquid includes the above white inorganic particles (second white inorganic particles), the binder, and the other components that are included when needed.

As a coating method, a known method such as gravure coating or bar coating may be used.

The coating liquid may be a water-based one that uses water as a coating solvent or a solvent-based one that uses an organic solvent such as toluene or methylethyl ketone. Of these, considering environmental burden, water is preferably used as the coating solvent. The coating solvent may be used in a manner of one kind alone or two or more kinds in a mixture. An example of preferable coating solvent includes water and a mixture of water and methyl alcohol (water/methyl alcohol=95/5 by mass ratio).

On the occasion of applying the coating liquid for a reflection layer, the coating liquid for a reflection layer is applied on the surface of a polymer base material directly or through an undercoat layer having a thickness of 2 μm or less, so that a reflection layer may be formed on the polymer base material.

Undercoat Layer

In the solar cell backsheet according to the present invention, an undercoat layer may be disposed between the polymer base material (support) and the reflection layer. The thickness of the undercoat layer is in a range of preferably 2 μm or less, more preferably from 0.05 μm to 2 μm, and still more preferably from 0.1 μm to 1.5 μm. When the thickness is 2 μm or less, face condition may be kept properly. When the thickness is 0.05 μm or more, necessary adhesiveness is easily secured.

The undercoat layer may include a binder therein. As the binder, for instance, polyester, polyurethane, acrylic resin, polyolefin, and the like may be used. In addition, to the undercoat layer, besides the binder, a cross-linking agent of epoxy-based, isocyanate-based, melamine-based, carbodiimide-based, oxazoline-based and the like, a surfactant such as anionic or nonionic, or filler such as silica may be added.

There is not any particular limitation on a method of applying the undercoat layer and on a solvent of the coating liquid that is used therein.

As a coating method, a gravure coater or a bar coater may be used.

The solvent used for the coating liquid may be water or an organic solvent such as toluene or methylethyl ketone. The solvent may be used in a manner of one kind alone or two or more kinds in a mixture.

Furthermore, application may be performed onto a polymer base material that has been biaxially stretched. In another method, application may be performed onto a polymer base material that has been uniaxially stretched, and then the polymer base material may be further stretched in a direction different from the uniaxial direction. In still another method, application may be performed onto a base material before being stretched, and then the base material may be stretched in two directions.

Properties

The solar cell backsheet according to the present invention exhibits a reflectance of preferably 85% or more when an incident light having a wavelength of 550 nm is entered from a side where the reflection layer is disposed. Note that, “reflectance” denotes a ratio of the amount of emission light to the amount of incident light, wherein the incident light that is entered from a front face of the solar cell backsheet is reflected on the reflection layer or on the reflection layer and the polymer base material and then emitted as the emission light.

When the reflectance is 85% or more, the light that passes through the cells and enters inside may be returned back to the cells effectively, whereby a large effect of increasing power generation efficiency is attained. By incorporating the white inorganic particles in the polymer base material and the reflection layer in an amount within the above ranges, the reflectance may be regulated at 85% or more.

Other Layers

The solar cell backsheet according to the present invention may include, when needed, an easy-to-adhere layer that serves to secure adhesion between a sealing material and the backsheet, a barrier layer (or sheet) that serves to prevent water penetration, a back layer (or sheet) that serves to protect the rear surface thereof, and the like.

Easy-To-Adhere Layer

The easy-to-adhere layer is a layer that serves to adhere firmly the solar cell backsheet and a sealing material that seals solar cell elements (hereinafter, also referred to as “power generation elements”) that are a main body of the cells.

Specifically, the easy-to-adhere layer is incorporated so as to attain an adhesion of 10 N/m or more and more preferably 20 N/m or more between the power generation elements that are a main body of the cells and an EVA-based sealing material.

The easy-to-adhere layer preferably includes therein: a binder such as polyester, polyurethane, acrylic resin, polyolefin, or acryl/silicone; a cross-linking agent of epoxy-based, isocyanate-based, oxazoline-based, carbodiimide-based, or the like; and particles such as silica or tin oxide.

The easy-to-adhere layer needs to be transparent in order not to lower the effect of the reflection layer.

The easy-to-adhere layer is formed by applying an easy-to-adhere polymer sheet to the polymer base material or applying a coating liquid for an easy-to-adhere layer onto the reflection layer or the like. Here, the components that are included in the easy-to-adhere layer are included in the coating liquid for an easy-to-adhere layer. A coating solvent that is used for preparing the coating liquid may be water or an organic solvent such as toluene or methylethyl ketone. The coating solvent may be used in a manner of one kind alone or two or more kinds in a mixture.

Barrier Layer

For the barrier layer (or sheet), a vacuum deposition layer of inorganic silica, aluminum oxide or the like or a sheet of metallic aluminum may be used.

The barrier layer may be formed by a method including: a method of forming a vacuum deposition layer of silica or aluminum oxide directly on the reflection layer or the polymer base material; and a method of applying a film having a vacuum deposition layer of silica or aluminum oxide directly onto the surface of the reflection layer or the polymer base material. In addition, a method of applying a sheet of metallic aluminum onto the reflection layer or the polymer base material may be included as a preferred embodiment.

Solar Cell Module

A solar cell module according to the present invention is configured as: solar cells that convert light energy of sun light into electrical energy are disposed between a transparent base board through which sun light enters and the above described solar cell backsheet according to the present invention; and a space between the base board and the backsheet is sealed with an ethylene-vinylacetate (EVA)-based sealing material.

Regarding members other than the solar cell module, the solar cells, and the backsheet, they are described in detail in “Taiyoko Hatsuden System Kosei Zairyo” (under the supervision of Eiichi Sugimoto, published by Kogyo Chosakai Publishing, Inc., 2008), for example.

The transparent base board may only has a light transparency to such an extent that sunlight is allowed to pass through it, and may be selected appropriately from base materials that allow light to transmit therethrough. From the viewpoint of power generation efficiency, a transparent base board that has a higher light transmittance is more preferable. For such a transparent base board, a glass base board, a transparent resin such as acrylic resin and the like may be suitably used, for example.

For the solar cell elements, various kinds of known solar cell elements may be used, including: solar cells based on silicon such as single crystal silicon, polycrystalline silicon, or amorphous silicon; and solar cells based on a III-V or II-VI compound semiconductor such as copper-indium-gallium-selenium, copper-indium-selenium, cadmium-tellurium, or gallium-arsenic. This application claims priority from Japanese Patent Application No. 2010-027998 filed on Feb. 10, 2010, the disclosure of which is incorporated by reference herein.

### EXAMPLE

The present invention will be further described in detail with reference to the following examples, but it should be construed that the present invention is in no way limited to those examples as long as not departing from the scope of the invention. Note that, if not otherwise specified particularly, “part(s)” and “%” are on the basis of mass.

Note that, volume average particle size was measured by using a laser diffraction particles size distribution analyzer “LA-950” (manufactured by HORIBA, Ltd.).

### Example 1

Preparation of Base Material 1 (Polymer Base Material)

Synthesis of Polyester

Slurry that included 100 kg of high purity terephthalic acid (manufactured by MITSUI CHEMICALS, INC.) and 45 kg of ethyleneglycol (manufactured by NIPPON SHOKUBAI CO., LTD.) was fed successively. over 4 hours to an esterification tank that was kept at a temperature of 250° C. and a pressure of 1.2×10⁵ Pa and was preliminary loaded with 123 kg or about 123 kg of bis(hydroxyethyl) terephthalate. After feeding was completed, esterification was still continued for 1 hour. After that, 123 kg of resulting esterification product were transferred to a polycondensation reactor tank.

Then, ethyleneglycol in an amount of 0.3% with respect to a polymer to be obtained was added to the polycondensation reactor tank where the esterification product had been transferred. After 5 minute agitation, an ethyleneglycol solution that contained cobalt acetate and another ethyleneglycol solution that contained manganese acetate were added in a manner that 30 ppm of cobalt acetate and 15 ppm of manganese acetate with respect to the polymer to be obtained were contained respectively in the resulting reaction mixture. After another 5 minute agitation, an ethyleneglycol solution that contained 2% of a titanium alkoxide compound was added in a manner that the content thereof became 5 ppm with respect to the polymer to be obtained. Five minute later, an ethyleneglycol solution that contained 10% of dimethyl phosphono ethylacetate was added in a manner that the content thereof became 5 ppm with respect to the polymer to be obtained. After that, the temperature of the reaction system was gradually elevated from 250° C. to 285° C. and the pressure was lowered to 40 Pa while the resulting low polymer was agitated at 30 rpm. The time elapsed until the temperature reached a final temperature and the time elapsed until the pressure reached a final pressure, both times were selected to be 60 minutes. At the time when an agitation torque reached a predetermined value, the reaction system was purged with nitrogen gas, so that the pressure was restored to normal pressure and that polycondensation was terminated. Then, by ejecting into cold water in a strand form and immediate cutting out, polymer pellets (about 3 mm dia. and about 7 mm long) were obtained. Note that, the time elapsed from the start of reducing pressure to the time when the agitation torque reached the predetermined value was 3 hours.

Note that, as the above titanium alkoxide compound, a titanium alkoxide (Ti content: 4.44%), which is synthesized in Example 1 described in the paragraph number [0083] of JP-A No. 2005-340616, was used.

Solid Phase Polymerization

Solid phase polymerization was carried out as: the above obtained pellets were left for 30 hours at 220° C. in a vacuum vessel that was kept at a pressure of 40 Pa.

Preparation of Titanium Dioxide Masterbatch

In a vacuum vessel equipped with an agitator, 5 kg of the pellets obtained after the solid-phase polymerization and 5 kg of “TIPAQUE PF739” (trade name: rutile-type titanium dioxide, manufactured by ISHIHARA SANGYO KAISHA, LTD.) were charged. They were kept at 285° C. under a pressure of 40 Pa for 2 hours while agitated.

After that, the reaction system was purged with nitrogen gas so as to be restored to normal pressure. By ejecting into cold water in a strand form and immediate cutting out, titanium dioxide masterbatches (about 3 mm dia. and about 7 mm long) were obtained.

Preparation of Base

The pellets obtained after the solid-phase polymerization and the titanium dioxide masterbatches were mixed in a mass ratio of 72/28 (total mass of the pellets obtained after the solid-phase polymerization/total mass of the titanium dioxide masterbatches) to obtain a mixture. The resulting mixture was fused at 280° C. and cast on a metal drum to form an about 0.8 mm thick non-stretched base. Then, the base was stretched at 90° C. in a longitudinal direction by 3 times, and further stretched at 120° C. in a transverse direction by 3.3 times. In this way, a 75 μm thick biaxially stretched polyethylene terephthalate support (hereinafter, referred to as “biaxially stretched PET”) was obtained.

Reflection Layer

Preparation of Titanium Dioxide Dispersion

Components included in the following composition were mixed and subjected to dispersing treatment for 1 hour with a dino-mill type dispersing machine.

Composition of Titanium Dioxide Dispersion
Titanium dioxide (0.42 μm of volume average particle size) [“TIPAQUE R-780-2” (trade name), manufactured by ISHIHARA SANGYO KAISHA, LTD., 100% of solid content]: 39.9%,
Polyvinylalcohol [“PVA-105” (trade name), manufactured by KURARAY CO., LTD., 10% of solid content]: 8.0%,
Surfactant [“DEMOL EP” (trade name), manufactured by Kao Corp., 25% of solid content]: 0.5%, and
Distilled water: 51.6%.

Preparation of Coating Liquid for Reflection Layer

Components included in the following composition were mixed so as to prepare a coating liquid for a reflection layer.

Composition of Coating Liquid
Titanium dioxide dispersion: 80.0%,
Polyacrylic resin water dispersion [binder: “JURYMER ET410” (trade name), manufactured by Nihon Junyaku Co., Ltd., 30% of solid content]: 19.2%,
Polyoxyalkylene alkylether [“NAROACTY CL95” (trade name), Sanyo Chemical Industries, Ltd., 1% of solid content]: 3.0%,
Oxazoline compound [cross-linking agent: “EPOCROS WS-700” (trade name), manufactured by NIPPON SHOKUBAI CO., LTD., 25% of solid content]: 2.0%, and
Distilled water: 7.8%.

Preparation of Reflection Layer

The resulting coating liquid was applied onto the one face of the biaxially stretched PET and dried at 180° C. for 1 minute, so that a reflection layer having a titanium dioxide content of 5.5 g/m² was prepared.

Thus obtained polymer sheet was served as a solar cell backsheet in Example 1.

Evaluation

Reflectance, properties, and weight of the solar cell backsheet in Example 1 were evaluated. The results are shown in Table 1.

1. Evaluation of Reflectance

An apparatus that was configured by attaching an integrating sphere attachment of “ISR-2200” (trade name) to a spectrophotometer of “UV-2450” (trade name: manufactured by Shimadzu Corp.) was used. Reflectance of 550 nm light on a face of a solar cell backsheet where a reflection layer was formed was measured. Note that, the reflectance of a barium sulfate standard plate was measured as a reference, which was evaluated to be 100%. The reflectance of the solar cell backsheet was calculated base on this reference.

A practically acceptable reflectance is 85% or more.

2. Properties

Properties (face condition) of the solar cell backsheet were observed by visual inspection or with an optical microscope, and were evaluated on the basis of the following evaluation criteria. Note that, the magnification of the optical microscope was selected to be 50 times. A 20 mm×50 mm surface area of the solar cell backsheet was observed.

Evaluation Criteria

Rank 5: no cracks are found on both front and rear faces even with the optical microscope,

Rank 4: no cracks are found on both front and rear faces by visual inspection, but slight cracks are found with the optical microscope,

Rank 3: no cracks are found on both front and rear faces by visual inspection, but cracks are found clearly with the optical microscope,

Rank 2: slight cracks are found by visual inspection, and

Rank 1: clear cracks are found on entire faces by visual inspection. Note that, this rank also includes a case where cracks are found only on the reflection layer.

A practically acceptable one is in a rank higher than rank 3.

Among the above evaluation criteria for the properties, rank 4 and rank 5 are within a practically acceptable range.

Note that, the front face denotes a sun light incident side (a side where the reflection layer is formed) of the surfaces of the solar cell backsheet. The rear face denotes an opposite face to the sun light incident side.

3. Evaluation for Solar Cell Backsheet Weight

The solar cell backsheet was cut into a size of 20 cm×30 cm and was subjected to humidity conditioning for 2 hours at 25° C. and 60% RH. After that, the weight of the solar cell backsheet was measured and converted into a weight for a 100 cm×100 cm solar cell backsheet.

### Example 2 to Example 10, Comparative Example 1 to Comparative Example 4

Solar cell backsheets of Example 2 to Example 10 and Comparative Example 1 to Comparative Example 4 were prepared substantially similar to the preparation of the solar cell backsheet in Example 1, except that the amount of polyethylene terephthalate (PET) in the polymer base material (base material 1), the amount of titanium dioxide (TiO₂) in the polymer base material (base material 1), the amount of binder in the reflection layer, and the amount of titanium dioxide (TiO₂) in the reflection layer were changed as shown in Table 1.

Note that, in Example 7 and Example 8, same reflection layers were formed on both face sides of the polymer base material (base material 1). The amount of binder and the amount of titanium dioxide in the column of “reflection layer” shown in Table 1 are the total amount of both faces.

Thus obtained solar cell backsheets were subjected to evaluation in a manner substantially similar to the solar cell backsheet in Example 1. The evaluation results were shown in Table 1.

### Comparative Example 5

Only the polymer base material (base material 1) that was used for the preparation of the solar cell backsheet in Example 1 was used for the solar cell backsheet in Comparative Example 5. Thus obtained solar cell backsheet was subjected to evaluation in a manner substantially similar to the solar cell backsheet in Example 1. Evaluation results were shown in Table 1.

### Comparative Example 6 to Comparative Example 8

The solar cell backsheets in Comparative Example 6 to Comparative Example 8 were obtained by changing, in the solar cell backsheet in Comparative Example 5, the thickness of the polymer base material and the amount of titanium dioxide in the polymer base material as shown in Table 1. Thus obtained solar cell backsheets were subjected to evaluation in a manner substantially similar to the solar cell backsheet in Example 1. The evaluation results were shown in Table 1.

### Comparative Example 9 to Comparative Example 11

A base material with a co-extruded layer was obtained by forming the co-extruded layer on the polymer base material (base material 1) that was used for the preparation of the solar cell backsheet in Example 1. Here, in the co-extruded layer, the amount of polyethylene terephthalate and the amount of titanium dioxide were in accordance with the amounts shown in the column of “co-extruded layer or base material 2” in Table 1.

Thus obtained base material with the co-extruded layer was used as the solar cell backsheets in Comparative Example 9 to Comparative Example 11. The backsheets were subjected to evaluation in a manner substantially similar to the solar cell backsheet in Example 1. The evaluation results were shown in Table 1.

The base material with the co-extruded layer was prepared specifically as follows.

The polyethylene terephthalate pellets that were used for the preparation of the polymer base material (base material 1) that was used for preparing the solar cell backsheet in Example 1 and the titanium dioxide masterbatches were mixed to obtain a mixture. The mixture was fused at 280° C. and co-extruded on a metal drum to form a non-stretched co-extruded base.

After that, the non-stretched co-extruded base was stretched at 90° C. in a longitudinal direction by 3 times, and further stretched at 120° C. in a transverse direction by 3.3 times to obtain the base material with the co-extruded layer.

### Comparative Example 12 to Comparative Example 14

A base material 2 was prepared in a manner substantially similar to the preparation of the polymer base material (base material 1) that was used for preparing the solar cell backsheet in Example 1, except that the amount of polyethylene terephthalate and the amount of titanium dioxide were changed to the amounts shown in the column of “co-extruded layer or base material 2” in Table 1.

The resulting base material 2 and the base material 1 were bonded together into solar cell backsheets in Comparative Example 12 to Comparative Example 14 by the following method.

Bonding Condition

As an adhesive agent, a mixture of “LX660(K)” (trade name) [adhesive agent, manufactured by DIC Corp.] and 10 parts of a curing agent of “KW75” (trade name) [adhesive agent, manufactured by DIC Corp.] was used. The base material 2 and the base material 1 were bonded together by hot-pressing with a vacuum laminator [vacuum lamination machine, manufactured by Nisshinbo Industries, Inc.].

Bonding was carried out by vacuum suction at 80° C. for 3 minutes and then pressing for 2 minutes. After that, reaction was completed by keeping at 40° C. for 4 days.

The resulting solar cell backsheets were subjected to evaluation in a manner substantially similar to the solar cell backsheet in Example 1. The evaluation results were shown in Table 1.

### Example 11

An easy-to-adhere layer was formed by applying a coating liquid for an easy-to-adhere layer on the opposite side of the face where the reflection layer was applied in the solar cell backsheet in Example 1.

Easy-To-Adhere Layer

Preparation of Coating Liquid for Easy-To-Adhere Layer

Components included in the following composition were mixed to prepare a coating liquid for an easy-to-adhere layer.

Composition of Coating Liquid
Polyolefin resin water dispersion liquid [binder: “CHEMIPEARL S75N” (trade name), manufactured by MITSUI CHEMICALS, INC., 24% of solid content]: 5.2 parts,
Polyoxyalkylene alkylether [“NAROACTY CL95” (trade name), Sanyo Chemical Industries, Ltd., 1% of solid content]: 7.8 parts,
Oxazoline compound [cross-linking agent: “EPOCROS WS-700” (trade name), manufactured by NIPPON SHOKUBAI CO., LTD., 25% of solid content]: 0.8 part,
Silica particle water dispersion (“AEROSIL OX-50” (trade name), manufactured by Nippon Aerosil Co., Ltd., 0.15 μm of volume average particle size, 10% of solid content): 2.9 parts, and
Distilled water: 83.3 parts.

Preparation of Easy-To-Adhere Layer

The resulting coating liquid was applied on a reflection layer in a manner that the amount of the binder was 0.09 g/m², and dried at 180° C. for 1 minute so as to prepare an easy-to-adhere layer. A member prepared in this way was named as a support A.

Preparation of Base Material 3

Pellets that were used for the preparation of the base material 1 that was used for preparing the solar cell backsheet in Example 1 were fused at 280° C. and cast on a metal drum to form a 0.5 mm thick non-stretched base. After that, the non-stretched base was stretched at 90° C. in a longitudinal direction by 3 times, and further stretched at 120° C. in a transverse direction by 3.3 times. In this way, a 50 μm thick biaxially stretched polyethylene terephthalate support (base material 3) was obtained.

On the one face of the resulting base material 3, the following back layer 1 was applied, and then a back layer 2 was applied on the back layer 1.

Back Layer 1

Preparation of Coating Liquid for Back Layer 1

Components included in the following composition were mixed so as to prepare a coating liquid for the back layer 1.

Composition of Coating Liquid
Acryl/silicone composite resin water dispersion [“CERANATE WAS 107D, manufactured by DIC Corp., 42% of solid content]: 45.9 parts,
Carbodiimide compound (cross-linking agent: “CARBODILITE V-02-L2” (trade name), manufactured by Nisshinbo Industries, Inc., 40% of solid content): 4.8 parts,
Polyoxyalkylene alkylether (“NAROACTY CL95” (trade name), Sanyo Chemical Industries, Ltd., 1% of solid content): 2.0 parts,
Titanium dioxide dispersion used in reflection layer: 33.0 parts, and
Distilled water: 14.3 parts.

Preparation of Back Layer 1

The resulting coating liquid was applied on a face opposite to the face of a base material on which a reflection layer was formed, in a manner that the amount of the binder was 3.0 g/m², and then dried at 180° C. for 1 minute to form the back layer 1.

After that, the following back layer 2 was formed on the back layer 1.

Back Layer 2

Preparation of Coating Liquid for Back Layer 2

Components included in the following composition were mixed to prepare a coating liquid for the back layer 2.

Composition of Coating Liquid
Fluoro resin water dispersion [“OBBLIGATO” (trade name), manufactured by AGC COAT-TECH CO., LTD., 42% of solid content concentration]: 45.9 parts,
Oxazoline compound [cross-linking agent: “EPOCROS WS-700” (trade name), manufactured by NIPPON SHOKUBAI CO., LTD., 25% of solid content]: 7.7 parts,
Polyoxyalkylene alkylether [“NAROACTY CL95” (trade name), Sanyo Chemical Industries, Ltd., 1% of solid content]: 2.0 parts,
Titanium dioxide dispersion used in reflection layer: 33.0 parts, and
Distilled water: 11.4 parts.

Preparation of Back Layer 2

The resulting coating liquid was applied on the back layer 1 in a manner that the amount of the binder was 2.0 g/m², and dried at 180° C. for 1 minute so as to prepare the back layer 2. A member prepared in this way was named as a support B.

Bonding

A solar cell backsheet in which the support A and the support B were bonded together was prepared by bonding them in a manner that the reflection layer of the support A and the non-coated face of the support B faced to each other and also in a manner substantially similar to Comparative Example 12.

### Example 12

Fabrication of Solar Cell Module

A 3 mm thick tempered glass, an EVA sheet [“SC50B” (trade name), manufactured by Mitsui Chemicals Fabro, Inc.], crystalline solar cells, an EVA sheet [“SC50B” (trade name), manufactured by Mitsui Chemicals Fabro, Inc.], and the solar cell backsheet in Example 11 were piled up in this order, which were then hot-pressed with a vacuum laminator (vacuum lamination machine, manufactured by Nisshinbo Industries, Inc.) so as to be bonded together with EVA. Note that, the backsheet was placed in a manner that the easy-to-adhere layer thereof contacted to the EVA sheet. EVA bonding conditions were as follows.

With the vacuum laminator, after vacuum suction at 128° C. for 3 minutes, by two minute pressing, temporary bonding was attained. After that, full bonding treatment was carried out in a dry oven at 150° C. for 30 minutes.

In this way, a crystalline solar cell module was fabricated. When power generation operation was carried out by using thus fabricated solar cell module, an adequate power generation performance as a solar cell was exhibited.

TABLE 1

| | Base Material 1 | | | Co-extruded | | | | | | | | | | | | |
|---|---|---|---|---|---|---|---|---|---|---|---|---|---|---|---|---|
| | (Polymer | | | layer or | | | | | | | | | | | | |
| | base material) | | | Base Material 2 | | | Reflection Layer | | | Backsheet Total | | | | Evaluation | | |
| | PET | TiO₂ | Rat. | PET | TiO₂ | Rat. | Binder | TiO₂ | Rat. | PET | TiO₂ | T.W. | Thick. | Reflec- | Pro- | Remarks |
| | [g/m²] | [g/m²] | % | [g/m²] | [g/m²] | [g/m²] | [g/m²] | [g/m²] | % | [g/m²] | [g/m²] | [g/m²] | [μm] | tance | perty | S.F.M. |
| Comp. Exp.1 | 99.8 | 16.2 | 14 | — | — | — | 15 | 5.5 | 27 | 114.8 | 21.7 | 137 | 87.2 | 81 | 5 | B1 + 1S |
| Exp.2 | 99.8 | 16.2 | 14 | — | — | — | 10 | 5.5 | 35 | 109.8 | 21.7 | 132 | 83.6 | 85 | 5 | B1 + 1S |
| Exp.3 | 99.8 | 16.2 | 14 | — | — | — | 5 | 5.5 | 52 | 104.8 | 21.7 | 127 | 80.0 | 87 | 5 | B1 + 1S |
| Exp.1 | 99.8 | 16.2 | 14 | — | — | — | 1 | 5.5 | 85 | 100.8 | 21.7 | 123 | 77.2 | 89 | 5 | B1 + 1S |
| Exp.4 | 99.8 | 16.2 | 14 | — | — | — | 0.7 | 5.5 | 89 | 100.5 | 21.7 | 122 | 77.0 | 90 | 4 | B1 + 1S |
| Comp. Exp.2 | 99.8 | 16.2 | 14 | — | — | — | 0.5 | 5.5 | 92 | 100.3 | 21.7 | 122 | 76.8 | 91 | 2 | B1 + 1S |
| Exp.5 | 99.8 | 16.2 | 14 | — | — | — | 0.6 | 3 | 83 | 100.4 | 19.2 | 120 | 76.3 | 85 | 4 | B1 + 1S |
| Exp.6 | 99.8 | 16.2 | 14 | — | — | — | 2 | 10 | 83 | 101.8 | 26.2 | 128 | 79.0 | 88 | 4 | B1 + 1S |
| Exp.7 | 99.8 | 16.2 | 14 | — | — | — | 2 | 10 | 83 | 101.8 | 26.2 | 128 | 79.0 | 91 | 5 | B1 + 2S |
| Exp.8 | 99.8 | 16.2 | 14 | — | — | — | 3 | 15 | 83 | 102.8 | 31.2 | 134 | 80.9 | 92 | 4 | B1 + 2S |
| Comp. Exp.3 | 102.1 | 8.9 | 8 | — | — | — | 1 | 5.5 | 83 | 103.1 | 14.4 | 118 | 77.1 | 76 | 5 | B1 + 1S |
| Exp.9 | 96.9 | 24.2 | 20 | — | — | — | 1 | 5.5 | 83 | 97.9 | 29.7 | 128 | 77.0 | 92 | 4 | B1 + 1S |
| Exp.10 | 92.8 | 36.1 | 28 | — | — | — | 1 | 5.5 | 83 | 93.8 | 41.6 | 135 | 76.9 | 94 | 3 | B1 + 1S |
| Comp. Exp.4 | 90.8 | 42.7 | 32 | — | — | — | 1 | 5.5 | 83 | 91.8 | 48.2 | 140 | 77.0 | 95 | 1 | B1 + 1S |
| Comp. Exp.5 | 99.8 | 16.2 | 14 | — | — | — | — | — | — | 99.8 | 16.2 | 116 | 75.1 | 79 | 5 | B1 |
| Comp. Exp.6 | 149.7 | 24.3 | 14 | — | — | — | — | — | — | 149.7 | 24.3 | 174 | 112.7 | 84 | 5 | B1 |
| Comp. Exp.7 | 199.6 | 32.4 | 14 | — | — | — | — | — | — | 199.6 | 32.4 | 232 | 150.3 | 88 | 4 | B1 |
| Comp. Exp.8 | 90.8 | 42.7 | 32 | — | — | — | — | — | — | 90.8 | 42.7 | 134 | 75.0 | 92 | 2 | B1 |
| Comp. Exp.9 | 99.8 | 16.2 | 14 | 35.0 | 16.2 | 0.32 | — | — | — | 134.8 | 32.4 | 167 | 104.0 | 94 | 1 | Co-Ex |
| Comp. Exp.10 | 99.8 | 16.2 | 14 | 67.4 | 16.2 | 0.19 | — | — | — | 167.2 | 32.4 | 200 | 127.1 | 92 | 4 | Co-Ex |
| Comp. Exp.11 | 99.8 | 16.2 | 14 | 99.8 | 16.2 | 0.14 | | | | 199.6 | 32.4 | 232 | 150.3 | 87 | 5 | Co-Ex |
| Comp. Exp.12 | 99.8 | 16.2 | 14 | 35.0 | 16.2 | 0.32 | — | — | — | 134.8 | 32.4 | 167 | 104.0 | 93 | 2 | B1 + B2 |
| Comp. Exp.13 | 99.8 | 16.2 | 14 | 67.4 | 16.2 | 0.19 | — | — | — | 167.2 | 32.4 | 200 | 127.1 | 92 | 4 | B1 + B2 |
| Comp. Exp.14 | 99.8 | 16.2 | 14 | 99.8 | 16.2 | 0.14 | — | — | — | 199.6 | 32.4 | 232 | 150.3 | 88 | 5 | B1 + B2 |

In Table 1, the abbreviation “Exp.” denotes “Example”, the abbreviation “Comp. Exp.” denotes “Comparative Example”, the abbreviation “Rat.” denotes “Ratio”, the abbreviation “T.W.” denotes “Total weight”, the abbreviation “Thick.” denotes “Thickness”, the abbreviation “S.F.M.” denotes “Sheet forming method”, the abbreviation “B1” denotes “Base Material 1”, the abbreviation “B2” denotes “Base Material 2”, the abbreviation “1S” denotes “Coating onto one side of the base material”, the abbreviation “2S” denotes “Coating onto both sides of the base material”, the abbreviation “Co-Ex” denotes “Co-extruded layer”, and the abbreviation “B1+B2” denotes “Lamination of Base Material 1 with Base Material 2”.

In Table 1, the term of “ratio” in the column of “base material 1” represents the ratio [%] of white inorganic particles with respect to the total mass of the base material 1. The term of “ratio” in the column of “reflection layer” represents the ratio [%] of white inorganic particles with respect to the total amount of the binder and the white inorganic particles included in the reflection layer.

As shown in Table 1, in all of the Examples, a reflectance of 85% or more was attained. Not only excellent reflectance and properties were attained, but also the weight of the solar cell backsheet was allowed to be kept equal to or less than 135 g/m², namely, weight saving was allowed to be provided.

According to the present invention, a solar cell backsheet that is lightweight and has a large reflectance, and a solar cell module that has excellent power generation efficiency may be provided.

The foregoing description of the exemplary embodiments of the present invention has been provided for the purposes of illustration and description. It is not intended to be exhaustive or to limit the invention to the precise forms disclosed. The embodiments were chosen and described in order to best explain the principles of the invention and its practical applications, thereby enabling others skilled in the art to understand the invention for various embodiments and with the various modifications as are suited to the particular use contemplated.

All publications, patent applications, and technical standards mentioned in this specification are herein incorporated by reference to the same extent as if such individual publication, patent application, or technical standard was specifically and individually indicated to be incorporated by reference. It will be obvious to those having skill in the art that many changes may be made in the above-described details of the preferred embodiments of the present invention. It is intended that the scope of the invention be defined by the following claims and their equivalents.

1. A backsheet for a solar cell, the backsheet comprising:
a polymer base material comprising first white inorganic particles in an amount of from 10% by mass to 30% by mass with respect to a total mass of the polymer base material; and
a reflection layer that is formed by being coated on at least one side of the polymer base material, the reflection layer comprising a binder, and second white inorganic particles in an amount of from 30% by mass to 90% by mass with respect to a total mass of the binder and the second white inorganic particles.

2. The backsheet for a solar cell according to claim 1, wherein the polymer base material is a polyester.

3. The backsheet for a solar cell according to claim 1, wherein at least one of the first white inorganic particles and the second white inorganic particles is titanium dioxide.

4. The backsheet for a solar cell according to claim 1, wherein an amount of the second white inorganic particles in the reflection layer is in a range of from 4 g/m² to 12 g/m².

5. The backsheet for a solar cell according to claim 1, wherein a volume average particle diameter of the first white inorganic particles and/or the second white inorganic particles is in a range of from 0.03 μm to 0.8 μm.

6. The backsheet for a solar cell according to claim 1, wherein the binder is selected from the group consisting of polyester, polyurethane, acrylic resin and polyolefin.

7. The backsheet for a solar cell according to claim 1 further comprising an undercoating layer between the polymer base material and the reflection layer, the undercoating layer having a thickness in a range of from 0.05 μm to 2 μm.

8. The backsheet for a solar cell according to claim 1 further comprising an adhesive layer on an opposite side of the polymer base material to which the reflection layer is disposed.

9. The backsheet for a solar cell according to claim 1, wherein a reflectance is 85% or more when an incident light having a wavelength of 550 nm is radiated toward a side where the reflection layer is disposed.

10. A module for a solar cell, the module comprising the backsheet for a solar cell according to claim 1.
